(19) United States
(12) Patent Application Publication
(10) Pub. No.: US 2011/0168975 A1
(43) Pub. Date: Jul. 14, 2011

(54) CAGED QUANTUM DOTS

(76) Inventor: Bruce Cohen, San Francisco, CA (US)

(21) Appl. No.: 13/000,819

(22) PCT Filed: Jul. 6, 2009
(86) PCT No.: PCT/US09/03965

§ 371 Date: Mar. 29, 2011

Related U.S. Application Data
(60) Provisional application No. 61/078,567, filed on Jul. 7, 2008.

(51) Int. Cl. H01L 33/06; H01L 29/06; B82Y 99/00; B82Y 20/00

(52) U.S. Cl. 257/13; 257/14; 257/E29.024; 257/E33.005; 977/774; 977/950

(57) ABSTRACT

Semiconductor nanocrystals known as quantum dots (QD) are caged by being associated with a molecule such as an orth-Nitrobenzyl (ONB) group. The luminescence of the QD is suppressed until activated by violet or ultra violet light.

### CROSS-REFERENCE

This application is a 371 National Phase application of International Application Serial No. PCT/US2009/003965, filed Jul. 6, 2009, which application claims priority to U.S. Provisional Patent Application Ser. No. 61/078,567, filed Jul. 7, 2008, both of which are incorporated herein by reference in their entirety noting that the current application controls to the extent there is any contradiction with an earlier application and to which applications we claim priority under 35 USC §120.

### GOVERNMENT SUPPORT

This invention was made with government support under Contract No. DE-AC02-05CH11231 awarded by Work at the Molecular Foundry and was supported by the Director, Office of Science, Office of Basic Energy Sciences, Division of Materials Sciences and Engineering, of the U.S. Department of Energy. The United States Government has certain rights in this invention.

### FIELD OF THE INVENTION

The invention relates generally to the field of semiconductor nanocrystals known as quantum dots (QD) and more particularly to caged QD with a compound which suppress QD luminescence until activated by an energy source such as UV irradiation.

### BACKGROUND OF THE INVENTION

Photoactivatable organic fluorophores have proven to be useful probes for increasing the temporal and spatial resolution in biological imaging experiments. (1) Similarly, genetically encoded fluorescent proteins (FPs) with photoswitchable optical properties have been widely adopted for cellular imaging (2, 3) and have been critical to the development of sub-diffraction microscopy techniques. (4,5) At the same time, semiconducting nanocrystal quantum dots (QDs) have proved to have superior brightness and photostability as compared to both organic fluorophores and FPs.

### SUMMARY OF THE INVENTION

In the development of nanoparticles with novel optical properties, synthesized photoactivatable, or “caged”, quantum dots, are disclosed and described here which are non-luminescent under typical microscopic illumination but can be activated to luminese with pulses of UV light.

The terms “caged quantum dot,” “caged QD,” “caged semiconductor nanocrystal” and the like are used here to describe a quantum dot associated with and/or bound to a molecule or group of molecules which render the quantum dot non-luminescent until pulsed with UV or violet light and include a QD bound to an ortho-Nitrobenzyl group (ONB). The adherence of the QD to the ONB or like molecule may be by any sort of bond, including, but not limited to, covalent, ionic, hydrogen bonding, Van der Waals' forces, or mechanical bonding, etc.

In earlier work ortho-Nitrobenzyl (ONB) chemistry has been used to cage biomolecules. Using ONB (molecules with O-nitrobenzyl moieties) renders the biomolecules inactive until pulsed with light. (6, 7) UV irradiation causes the ONB to undergo a bond-cleaving photoreaction. This reaction frees the parent molecule along with a nitrosocarbonyl byproduct. With QDs, various aromatic groups have previously been found to either quench (8, 9) or enhance (10) luminescence. In connection with the present invention we show that ONB groups efficiently suppress QD luminescence when tethered to the nanoparticle surface (FIG. 1). Quantum dots with a core/shell of CdTe/CdS core/shell were grown under aqueous conditions in the presence of mercaptopropionic acid (MPA), (11, 12) and lipoic acid-derived dithiolate ligands (13) were synthesized to contain an ONB-phosphoryl group. The phosphoryl group was chosen because it has proven to be an excellent substrate for caging groups (7, 14) and because of its solubility in water; the DMNPE caging group (27) absorbs at the longer UV wavelengths commonly used to photoswitch genetically-encoded fluorescent proteins (FPs), and it produces a nitrosoketone byproduct less toxic than those of other caging groups.

Mixtures of compound 3 (synthesized as in FIG. 1) and its non-caged analog 4 were added to the nanoparticles and allowed to displace the monothiol 3-mercaptopropionic acid (MPA). Exchange occurred very rapidly upon mixing, judging from a readily observed loss of luminescence within the first few seconds. This method of MPA displacement on water-grown QDs permits facile preparation of varying percentages of caging groups onto the QD surface, as seen in their absorbance spectra (FIG. 2a). It also avoids residual surfactant from inorganic preparations that can lead to background cell staining, and permits the addition of a percentage of other ligands for bioconjugation and cell compatibility.(15)

Green CdTe/CdS QDs (λmax=520 nm) coated with 25% caged compound 3 showed a ca. 400-fold reduction in photoluminescence (PL) quantum yield compared to identical QDs coated with non-caged 4 (FIG. 2b and FIG. 3a). Lowering the fraction of 3 to 10% decreased the effect to a 250-fold reduction. ONB-coated QDs also exhibited a small shift in emission (ca. 5 nm) and first exciton (3 nm) peaks to higher energies. Comparing these caged QDs to other imaging probes, the difference between dark and bright states of UV-GFP is ca. 100-fold, (2) and the “fully quenched” state of dopamine-coated CdSe/ZnS QDs is described as “>100-fold”.(9) This contrast ratio between dark and bright states is critical to the success of computational approaches to superresolution microscopy, with larger contrasts allowing more precise localization of individual probes. (5)

Exposure of caged QDs to 2 mW/mm² 365-nm light leads to increases in PL, as would be expected if the ONB byproduct is photolytically released from the QD surface (FIGS. 2a-c). Non-caged QDs also typically showed an increase in quantum yield, though much smaller (ca. 1.1- to 1.4-fold) than for the caged QDs, consistent with previous reports of photobrightening effects caused by annealing of surface traps. (11, 17, 18) Longer illumination times led to full restoration of 3-caged QD luminescence (FIGS. 2c and 3a), and at the longest times we consistently (n>5) and unexpectedly saw caged QDs become brighter than their non-caged counterparts exposed to the same conditions.

To determine how the distance between ONB and nanocrystal affects luminescence, a second lipoic acid derivative 5 (FIG. 1b), was synthesized with the ONB held fewer atoms from the QD surface than with 3. QDs coated with this compound showed consistently lower PL yields than identical QDs coated with similar percentages of 3 (FIG. 3a). The PL increase was less efficient for QDs coated with 5, possibly owing to the thiol being a poorer uncaging substrate than phosphate, and compound 3 was used in all further experiments.

Work was carried out to understand how ONB interacts with QDs of different compositions and emissions. Green InP/ZnS QDs (ref. 19, λₘₐₓ=524 nm) were quenched 30-fold by a 25% ONB surface coating, about an order of magnitude less than comparable green CdTe/CdS QDs, possibly due to differences in shell thickness. Red CdTe/CdS QDs (λₘₐₓ=625 nm) also displayed quenching by surface-bound ONB, though to a significantly lesser degree than the green QDs. For near infrared (nIR) CdHgTe/ZnS QDs (ref. 20, λₘₐₓ=760 nm), quenching was lesser still, about 25-fold, even with a 100% surface coating. For all QDs, quenching increased with increasing fractions of surface ONB, although this effect saturated at a certain fraction, and saturation occurred at lower percentages with green QDs than with longer wavelength QDs. Importantly, we observe that ONB cages QDs over a wide spectral window, from green into the nIR.

One possible mechanism of ONB quenching would involve an inner filter effect, in which surface-bound ONB groups absorb photons before they can reach the nanocrystal. To determine if such screening contributes to ONB quenching, an examination was made of red CdTe/CdS ONB-coated QDs excited at the first exciton, where ONB has no measurable absorbance (FIG. 2a). These QDs still showed a decrease in PL quantum yield, but this decrease is less than found with 405-nm excitation. This shows some inner filter effect, but the observed quenching with 605-nm excitation suggests the primary effect arises from a non-radiative coupling of the ONBs with the nanocrystal.

Further work was carried out to examine these red and green QDs with time-correlated single-photon counting spectroscopy (TCSPC) to determine if ONB affects in the exciton lifetime (FIG. 3). PL lifetimes of caged QDs were shorter than non-caged QDs and decreased with increasing numbers ONB ligands. As with steady-state PL, this effect is more pronounced for QDs of shorter wavelength emissions. These lifetimes are an indication that that ONB creates a new non-radiative pathway that depends on the number of ONBs on the surface and the emission of the QD.

Quantum dots were produced with the ability to be switched on with light, one of the more useful properties of bioimaging probes. The ONB caging group efficiently quenches QD luminescence and can be released from the nanoparticle surface with UV light. This caging is dependent on the emission of the QD but it is effective through the visible spectrum into the nIR, offering a large array of new colors for photoactivatable probes. Like photoactivatable organic and FP probes, caged QDs can confer increased spatial and temporal resolution in biological imaging experiments, with the increased brightness and photostability of QDs. The QDs may be used as superresolution probes.

These and other objects, advantages, and features of the invention will become apparent to those persons skilled in the art upon reading the details of the caged quantum dots and their method of use as more fully described below.

### BRIEF DESCRIPTION OF THE DRAWINGS

The invention is best understood from the following detailed description when read in conjunction with the accompanying drawings. It is emphasized that, according to common practice, the various features of the drawings are not to-scale. On the contrary, the dimensions of the various features are arbitrarily expanded or reduced for clarity. Included in the drawings are the following figures:

FIG. 1 includes 1A which is a schematic representation of a quantum dot uncaging with o-nitrobenzyl ligands. FIG. 1B shows a reaction scheme for phosphoryl-ONB lipoic acid ligand synthesis, and structures of other surface ligands used.

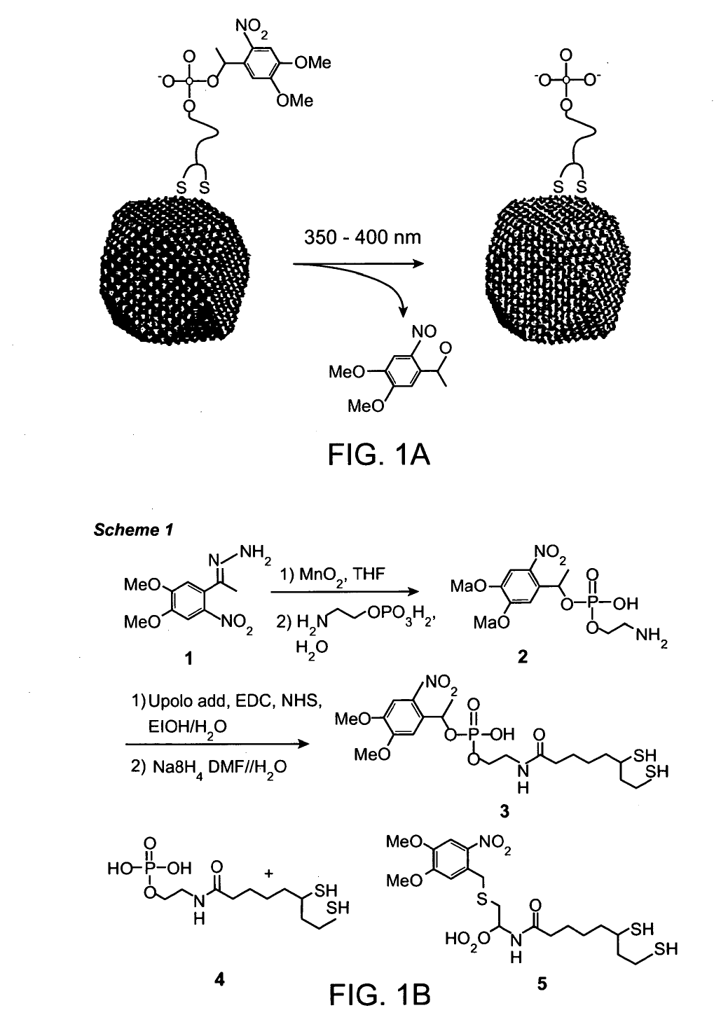

FIG. 2 includes four different graphs A, B, C and D. The graph 2A shows an absorbance spectra of CdTe/CdS QDs and surface ligands. QD concentrations are 1.5 μM and free ligand is 90 μM, in 100 mM phosphate buffer, pH 7.4. Graph 2B shows a photoluminescence spectra of CdTe/CdS QDs (λmax=520 nm) with varying percentages of ONB ligand 3, excited at 405 nm. Inset shows the same data with Y-axis expanded 150-fold. All spectra are normalized to the absorbance at the first exciton. Graph 2C shows a PL spectra of QDs represented in the graph 2B following 2 minutes of 2 mW/mm² 365-nm irradiation. The graph 2D shows the PL spectra of QDs in Graph 2B following 10 minutes of irradiation.

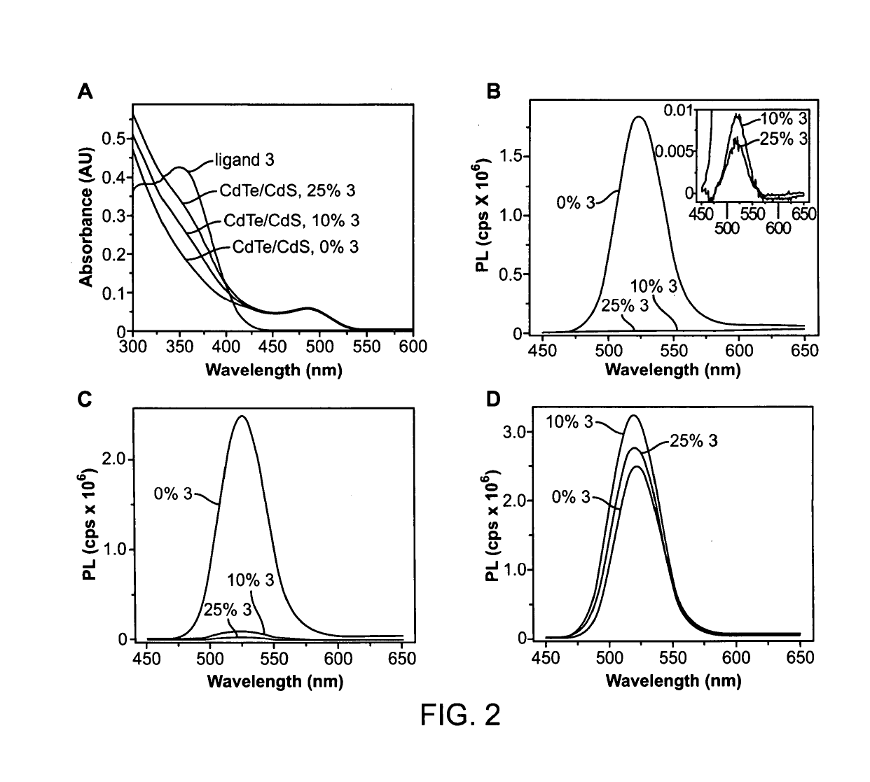

FIG. 3 includes graphs A and B. Graph A shows the transient PL emission of green CdTe/CdS QDs (λₘₐₓ=525 nm), excited at 440 nm and detected with TCSPC. Graph B shows the transient PL emission of red CdTe/CdS QDs (λₘₐₓ=625 nm).

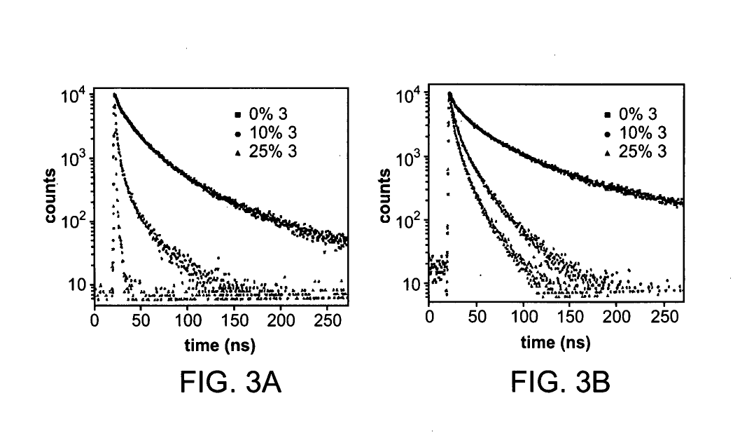

### DETAILED DESCRIPTION OF THE INVENTION

Before the present caged quantum dots are described, it is to be understood that this invention is not limited to particular molecules or semiconductor nanocrystals described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed within the invention. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included in the invention.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, some potential and preferred methods and materials are now described. All publications mentioned herein are incorporated herein by reference to disclose and describe the methods and/or materials in connection with which the publications are cited. It is understood that the present disclosure supercedes any disclosure of an incorporated publication to the extent there is a contradiction.

It must be noted that as used herein and in the appended claims, the singular forms “a”, “an”, and “the” include plural referents unless the context clearly dictates otherwise. Thus, for example, reference to “a quantum dot” includes a plurality of such quantum dots and reference to “the ONB molecule” includes reference to one or more ONB molecules and equivalents thereof known to those skilled in the art, and so forth.

The publications discussed herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed.

### DEFINITIONS

The terms “caged quantum dot” and “caged semiconductor nanocrystal” and “caged QD” and the like refer to a semiconductor nanocrystal bound to or associated with a group, a molecule or group of molecules which renders the semiconducting nanocrystal non-luminescent. The caged quantum dot can be understood to have its luminescence quenched by a surface ligand containing a chemical quenching group which may be an aromatic group and particularly an ortho-nitrobenzyl group (ONB). The caged quantum dot has its luminescence restored by cleaving away the attached chemical group such cleaving away the aromatic group or ortho-nitrobenzyl group from the nanocrystal using a pulse of light which light may be violet light or ultraviolet light. The adherence of the QD to the ONB or like molecule may be any sort of bond, including, but not limited to, covalent, ionic, hydrogen bonding, Van der Waals' forces, or mechanical bonding, etc.

The term “non-luminescent” is intended to mean that the particles such as the caged semiconducting nanocrystal has a luminescence quantum yield of less than 0.5%, or less than 0.1%. The term encompasses particles which do not emit any light at all. Particularly, the term encompasses a caged quantum dot which does not emit light or emits 0.5% or less or 0.1% or less of light until the caged quantum dot is exposed to violet or ultraviolet light which cleaves away the quenching compound such as cleaving away the ortho-nitrobenzyl group. The UV light is generally understood to have a frequency between 300 to 400 nm and violet light is generally understood to have a frequency between 400 and 420 nm. Thus, the frequency used to cleave the attached group can have an overall range of from 300 to 420 nm.

By use of the terms “nanometer crystal” or “nanocrystal” and the like is meant an organic or inorganic single crystal particle having an average cross-section no larger than about 20 nanometers (nm) or 20×10⁻⁹ meters (200 Angstroms), preferably no larger than about 10 nm Angstroms) and a minimum average cross-section of about 1 nm, although in some instances a smaller average cross-section nanocrystal, i.e., down to about 0.5 nm (5 Angstroms), may be acceptable. Typically the nanocrystal will have an average cross-section ranging in size from about 1 nm (10 Angstroms) to about 10 nm (100 angstroms).

By use of the term “semiconductor nanocrystal” is meant a nanometer crystal or nanocrystal of Group II-VI and Group III-V semiconductor compounds capable of emitting electromagnetic radiation upon excitation, although the use of Group IV semiconductors such as germanium or silicon, or the use of organic semiconductors, may be feasible under certain conditions.

By use of the term “a narrow wavelength band”, with regard to the electromagnetic radiation emission of the semiconductor nanocrystal, is meant a wavelength band of emissions not exceeding about 40 nm, and preferably not exceeding about 20 nm in width and symmetric about the center, in contrast to the emission bandwidth of about 100 nm for a typical dye molecule, with a red tail which may extend the band width out as much as another 100 nm. It should be noted that the bandwidths referred to are determined from measurement of the width of the emissions at half peak height (FWHM), and are appropriate in the range of 200 nm to 2000 nm

By use of the term “a broad absorption band”, with regard to the electromagnetic radiation absorption of the semiconductor nanocrystal is meant a continuously increasing absorption from the onset, which occurs near to, but at slightly higher energy than the “narrow wavelength band” of the emission. This is in contrast to the “narrow absorption band” of dye molecules which occurs near the emission peak on the high energy side, but drops off rapidly away from that wavelength.

By use of the term “detectable substance” is meant an entity or group, the presence or absence of which in a material such as a biological material, is to be ascertained by use of the organo-luminescent semiconductor nanocrystal probe of the invention.

By use of the term “affinity molecule” is meant the portion of the organo luminescent semiconductor nanocrystal probe of the invention which will selectively bond to a detectable substance (if present) in the material (e.g., biological material) being analyzed.

By use of the term “linking agent” is meant a substance capable of linking with a semiconductor nanocrystal and also capable of linking to either an ortho-nitrobenzyl (ONB) group or an affinity molecule.

The terms “link” and “linking” are meant to describe the adherence between an ortho-Nitrobenzyl (ONB) group or the affinity molecule and the semiconductor nanocrystals, either directly or through a moiety identified herein as a linking agent. The adherence may comprise any sort of bond, including, but not limited to, covalent, ionic, hydrogen bonding, Van der Waals' forces, or mechanical bonding, etc.

The terms “bond” and “bonding” are meant to describe the adherence between an ortho-Nitrobenzyl (ONB) group or the affinity molecule and the detectable substance. The adherence may comprise any sort of bond, including, but not limited to, covalent, ionic, or hydrogen bonding, Van der Waals' forces, or mechanical bonding, etc.

The term “luminescent semiconductor nanocrystal compound”, as used herein, is intended to define a semiconductor nanocrystal linked to one or more linking agents and capable of linking to an affinity molecule, while the term “organo-luminescent semiconductor nanocrystal probe” is intended to define a luminescent semiconductor nanocrystal compound linked to an affinity molecule.

### INVENTION IN GENERAL

Caged semiconductor nanocrystals are disclosed which are comprised of one or more semiconductor nanocrystal components which has bound thereto or associated therewith a chemical moiety which has two basic properties. First, the moiety renders the semiconductor nanocrystal non-luminescent. Second, the moiety has an available photolysis pathway which upon the application of light separates the moiety away from the semiconductor nanocrystal thereby removing the quenching effect. A wide range of different types of semiconductor nanocrystal molecules can be used in connection with the present invention. There are specific examples provided here. Further, the term “semiconductor nanocrystals” is broadly defined above. Still further, applicant incorporates by reference U.S. Pat. No. 5,990,479 for the purpose of disclosing and describing various types of semiconductor nanocrystals.

The semiconductor nanocrystals useful in the practice of the invention include nanocrystals of Group II-VI semiconductors such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe; and nanocrystals of Group III-V semiconductors such as GaAs, InGaAs, InP, and InAs. As mentioned above, the use of Group IV semiconductors such as germanium or silicon, or the use of organic semiconductors, may also be feasible under certain conditions.

Formation of nanometer crystals of Group III-V semiconductors is described in U.S. Pat. No. 5,251,018; Alivisatos et al. U.S. Pat. No. 5,505,928; and Alivisatos et al. U.S. Pat. No. 5,262,357, which also describes the formation of Group II-VI semiconductor nanocrystals, all of which are also incorporated here by reference. Also described therein is the control of the size of the semiconductor nanocrystals during formation using crystal growth terminators.

The nanocrystals may be used in a core/shell configuration wherein a first semiconductor nanocrystal forms a core ranging in diameter, for example, from about 20 Angstroms to about 100 Angstroms, with a shell of another semiconductor nanocrystal material grown over the core nanocrystal to a thickness of, for example, 1-10 monolayers in thickness. When, for example, a 1-10 monolayer thick shell of CdS is epitaxially grown over a core of CdSe, there is a dramatic increase in the room temperature photoluminescence quantum yield. Formation of such core/shell nanocrystals is described more fully in a publication by one of us with others entitled “Epitaxial Growth of Highly Luminescent CdSe/CdS Core/Shell Nanocrystals with Photostability and Electronic Accessibility”, by Peng, Schlamp, Kadavanich, and Alivisatos, published in the Journal of the American Chemical Society, Volume 119, No. 30, 1997, at pages 7019-7029, the subject matter of which is hereby specifically incorporated herein by reference.

The semiconductor nanocrystals used in the invention generally have a capability of emitting light within a narrow wavelength band of about 40 nm or less, preferably about 20 nm or less, thus permitting the simultaneous use of a plurality of differently colored organo luminescent semiconductor nanocrystal probes with different semiconductor nanocrystals without overlap (or with a small amount of overlap) in wavelengths of emitted light (unlike the use of dye molecules with broad emission lines (e.g., about 100 nm) and broad tails of emission (e.g., another 100 nm) on the red side of the spectrum), thus allowing for the simultaneous detection of a plurality of detectable substances. The caged effect allows the signal to be “on” or “off” as desired.

The terms “nanometer crystal” or “nanocrystal” can encompass an organic or inorganic single crystal particle having an average cross-section no larger than about 20 nanometers (nm) or 20×10⁻⁹ meters (200 Angstroms), preferably no larger than about 10 nm (100 Angstroms) and a minimum average cross-section of about 1 nm, although in some instances a smaller average cross-section nanocrystal, i.e., down to about 0.5 nm (5 Angstroms), may be acceptable. Typically the nanocrystal will have an average cross-section ranging in size from about 1 nm (10 Angstroms) to about 10 nm (100 angstroms).

The term “semiconductor nanocrystal” can encompass a nanometer crystal or nanocrystal of Group II-VI and Group III-V semiconductor compounds capable of emitting electromagnetic radiation upon excitation, although the use of Group IV semiconductors such as germanium or silicon, or the use of organic semiconductors, may be feasible under certain conditions.

The caged semiconductor nanocrystals of the present invention may be attached to a linking agent. The linking agent can be any moiety which attaches to the caged semiconductor nanocrystal and is attachable to some other molecule such as biologically active molecule. Various types of linking groups are also disclosed within U.S. Pat. No. 5,990,479 and will be apparent to those skilled in the art upon reading this disclose and the '479 patent.

A caged luminescent semiconductor nanocrystal probe of the invention will usually find utility with respect to the detection of one or more detectable substances in organic materials, and in particular to the detection of one or more detectable substances in biological materials. This requires the presence, in the organo-luminescent semiconductor nanocrystal probe, of an affinity molecule or moiety, as described above, which will bond the organo-luminescent semiconductor nanocrystal probe to the detectable substance in the organic/biological material so that the presence of the detectable material may be subsequently ascertained. However, since the semiconductor nanocrystals are inorganic, they may not bond directly to the organic affinity molecule. In these cases, therefore, there must be some type of linking agent present in the organo-luminescent semiconductor nanocrystal probe which is capable of forming a link to the inorganic semiconductor nanocrystal as well as to the organic affinity molecule in the organo-luminescent semiconductor nanocrystal probe.

In order to further disclose and describe the invention a number of examples are provided below of caged semiconductor nanocrystals. These caged semiconductor nanocrystals are comprised of a basic semiconductor nanocrystal component which has bound thereto or associated therewith a chemical moiety which renders the semiconductor nanocrystal non-luminescent, and further wherein the chemical moiety is cleaved from the semiconductor nancrystal by the application of light which light is generally violet or ultraviolet light.

### EXAMPLES

The following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g. amounts, temperature, etc.) but some experimental errors and deviations should be accounted for. Unless indicated otherwise, parts are parts by weight, molecular weight is weight average molecular weight, temperature is in degrees Centigrade, and pressure is at or near atmospheric.

### Materials and Analysis.

All compounds were of the highest available purity and purchased from Sigma-Aldrich, except aluminum telluride (MB Biochemicals), and tris(trimrthylsilyl)phosphine and zinc stearate (Alfa Aesar). ESI-MS were measured on an Agilent LC/MSD Trap XCT, NMR spectra on a 500 MHz Bruker Biospin Avance II 500 MHz High Performance NMR Spectrometer, luminescence spectra on a Jobin Yvon Fluoromax-4 Spectrophotomer, and absorbance spectra on a PerkinElmer UV35 Spectrometer.

### Ligand Synthesis.

LA-(DMNPE)phosphate. Hydrazone 1 (150 mg, 0.63 mmol, prepared as in (ref. 23) was dissolved in 3 mL of THF, and MnO₂ (174 mg, 2.00 mmol) was added in the dark. The reaction was stirred for 5 min and filtered into O-phosphorylethanolamine (71 mg, 0.50 mmol) stirring in 3 mL of water and 3 mL of ether. The reaction was stirred well overnight, open and in the dark, allowing most of the organics to evaporate. In a separate flask, lipoic acid (113 mg, 0.55 mmol) and N-hydroxysuccinimide (63 mg, 0.55 mmol) were dissolved in 3 mL of EtOH, 1 mL of 0.5 M NaHCO₃, and 1 mL of 0.5 M MES buffer, pH 4.5. EDC (101 mg, 0.53 mmol) was added and the reaction stirred overnight. The caged phosphate solution was washed with 2×10 mL of CH₂Cl₂ and added to the lipoic acid solution, along with 2 mL of 0.5 M sodium phosphate, pH 7.4. This reaction was stirred for 14 h, and the solution was acidified to pH 4 with citrate buffer and purified by preparative C₁₈ HPLC (a linear gradient of 2 to 60% CH₃CN over 30 min, with 0.1% TFA), with product eluting at 44% CH₃CN, yielding 88 mg (33%) of yellow solid. ESI-MS: m/z 539.1 [M+H]⁺. ¹H NMR (DMSO-d6) δ 7.97 (m, 1H), 7.59 (s, 1H), 7.23 (s, 1H), 5.86 (m, 1H), 3.93 (s, 3H), 3.87 (s, 3H), 3.76 (m, 2H), 3.62 (m, 2H), 3.15 (m, 3H), 2.41 (m, 2H), 2.21 (t, 7.1, 2H), 1.94 (m, 1H), 1.58-1.37 (m, 10H).

Compound 3 (DHLA-(DMNPE)phosphate). LA-(DMNPE)phosphate (56 mg, 0.10 mmol) was dissolved in 4 mL of DMF and 4 mL of 0.2M sodium phosphate, pH 7.4. NaBH₄ (12 mg, 0.31 mmol) was added and stirred under N₂ for 1 h. Semi-preparative C₁₈ HPLC (2 to 60% CH₃CN over 30 m) gave a sole yellow peak at 38% CH₃CN, which lyophilized to 40 mg (71%) powder. ESI-MS: m/z 541.0 [M+H]⁺. ¹H NMR (CD₃OD) δ 7.66 (s, 1H), 7.38 (s, 1H), 6.06 (m, 1H), 4.00 (s, 3H), 3.93 (s, 3H), 3.85 (m, 2H), 3.41 (m, 2H), 2.92 (m, 1H), 2.72 (m, 2H), 2.33 (t, 7.3, 2H), 2.20 (t, 7.4, 2H), 1.92 (m, 1H), 1.71-1.49 (m, 10H).

LA phosphate. Lipoic acid (103 mg, 0.5 mmol) and N-hydroxysuccinimide (60 mg, 0.52 mmol) were dissolved in 3 mL of DMF and 1 mL of 0.5 M NaHCO₃. O-Phosphorylethanolamine (74 mg, 0.52 mmol) was dissolved in 2 mL of 0.2M sodium phosphate, pH 7.4, and added, followed by EDC (101 mg, 0.52 mmol), and the reaction was stirred overnight. The solution was acidified to pH 4 with citrate buffer and purified by preparative C₁₈ HPLC (a linear gradient of 2 to 60% CH₃CN over 30 min, with 0.1% TFA), with product eluting at 35% CH₃CN. Lyophilization yielded 122 mg (74%) of waxy ecru solid. ESI-MS: m/z 329.7 [M+H]⁺. ¹H NMR (DMSO-d₆) δ 3.80 (t, 6.6, 2H), 3.55 (m, 1H), 3.25 (m, 2H), 3.05 (m, 2H), 2.34 (t, 6.6, 1H), 2.09 (t, 6.0, 2H), 1.84 (m, 1H), 1.61-1.28 (m, 7H).

Compound 4 (DHLA phosphate). LA phosphate (100 mg, 0.30 mmol) was suspended in 5 mL of DMF and 4 mL of H₂O. NaBH₄ (35 mg, 0.91 mmol) in 1 mL of water was added, and the reaction clarified as it stirred overnight. Preparative HPLC as above yielded 80 mg (79%) of white solid eluting at 30% CH₃CN. ESI-MS: m/z 331.7 [M+H]⁺. ¹H NMR (D₂O) δ 3.81 (dd, 11.9, 5.6, 2H), 3.30 (t, 5.2, 2H), 2.87 (m, 1H), 2.55 (m, 2H), 2.15 (t, 7.3, 2H), 1.79 (dd, 12.9, 8, 1H), 1.65-1.35 (m, 7H).

Compound 5 (DHLA-Cys(DMNB)). To 75 mg (0.15 mmol) of LA-Cys(DMNB) dissolved in 1 mL of EtOH was added NaBH₄ (17 mg, 0.45 mmol) in 1 mL of H₂O. The reaction was stirred for 2 h and then purified by semi-preparative C₁₈ HPLC (2 to 60% CH₃CN over 30 min). Product (m/z=507.3) eluted at 32% CH₃CN and was lyophilized to 55 mg (73%) of yellow powder. ESI-MS: m/z 507.3 μM+Hr. ¹H NMR (CD₃OD) δ 8.00 (s, 1H), 7.70 (s, 1H), 7.15 (s, 1H), 4.52 (m, 1H), 4.14 (s, 2H), 4.01 (s, 3H), 3.92 (s, 3H), 3.11 (m, 2H), 2.85 (m, 3H), 2.27 (t, 4.9, 2H), 1.91 (m, 1H), 1.68-1.50 (m, 7H).

### Nanoparticle Synthesis

CdTe/CdS core/shell nanocrystals were synthesized under aqueous conditions following previous protocols. (11, 12, 18, 24) In a typical synthesis, Cd(OCl₄)2(H₂O) (165 mg, 0.5 mmol) was dissolved in 75 mL of N₂-purged H₂O with 3-mercaptopropionic acid (MPA, 54 μL, 0.62 mmol), and the pH adjusted to 12.0 with 5 M NaOH. The solution was again purged with N₂ and, in a separate flask, 5 mL of 0.5 M H₂SO₄ was added slowly to Al₂Te₃ (44 mg, 0.1 mmol). The resulting H₂Te was bubbled through the cadmium solution under N₂ pressure, causing the solution to turn orange. The solution was then heated to 100° C. and progress monitored by the luminescence emission spectrum. The reaction was stopped ca. 10 nm shy of the desired emission maximum by cooling the reaction to room temperature under N₂. Thioacetimide (8 mg, 0.1 mmol) dissolved in 1 mL of H₂O was added and the solution heated to 70° C. for 20 min The reaction was cooled and concentrated to 4 mL by spin dialysis (Amico Ultra 10k MWCO). The nanoparticles were washed with 2×25 mL of 0.1 M phosphate buffer, pH 8, and MPA was added to 10 mM for storage. Typical PL quantum yields of these QDs with MPA coatings were 20-25%.

For ligand exchange, excess MPA was removed by spin dialysis (Microcon, 10k MWCO) and the nanoparticles redissolved to ca. 10 μM in 0.1 M phosphate buffer, pH 8, in a 4 mL glass vial. Ligand from a 100 mM stock solution was added to 20 mM, the vial purged with N₂ and sealed, and the reaction vortexed well. Quenching ligands appeared to exchange onto the nanoparticles very rapidly, based on loss of luminescence under UV illumination. Closed vials were set in the dark overnight, and excess ligand was again removed by spin dialysis prior to use.

The InP/ZnS core/shell nanocrystals were synthesized essentially as described previously. (19) Indium acetate (0.4 mmol), myristic acid (1.45 mmol) and octadecene (ODE, 4 g) were loaded into a 25 mL three-neck flask and heated to 188° C. under N₂ flow. P(TMS)₃ (0.2 mmol) and octylamine (2.4 mmol) were dissolved in ODE (590 μL) in a glove box and the P(TMS)₃ solution was then rapidly injected into the hot reaction mixture. The growth of InP nanocrystals was carried out at 178° C. and monitored by UV-Vis absorption. After 30 min, the reaction was cooled to 150° C. Zinc stearate (1.2 mL of 0.1 M ODE solution) and sulfur (1.2 mL of 0.1 M ODE solution) were injected into the reaction flask sequentially within 10 min intervals at 150° C. The reaction temperature was then increased to 220° C. for 30 mM to allow the growth of ZnS shell. This addition was then repeated with 1.6 mL precursor solutions. The reaction was stopped by cooling to room temperature. The as-prepared InP/ZnS nanoparticles were further purified by successive methanol extractions.

MPA (300 μL) was added into a 1 μM solution of InP/ZnS nanoparticles in chloroform (1 mL) and stirred overnight at room temperature. The nanoparticles were isolated from opaque solution via centrifugation, and the resulting pellet was rinsed twice with chloroform. The nanoparticles were then resuspended in a 1.1 mM aqueous solution of MPA (pH=10) and incubated at room temperature for 24 h to finalize ligand exchange. The solution was extracted 2 times with chloroform and stored under N₂. The PL quantum yield of these QDs with MPA coating was 10%. Lipoic acid derivative ligand exchange was carried out as with the CdTe/CdS nanoparticles.

CdHgTe/ZnS QDs (20) and mixed-dimension CdSe/CdS dot/rods (21) were synthesized essentially as described, and transfer to water was carried out as above.

### Photolysis and Luminescence

All measurements were carried out in 100 mM phosphate buffer, pH 7.4. QD concentrations were determined according to extinction coefficient formulas reported in (ref. 16). QD's were dissolved to 1 μM in 100 mM phosphate buffer, pH 7.4, and photolyzed under ambient conditions in a UVP CL-100 cross-linker equipped with 8-mW 365-nm bulbs. Light intensity was measured at 2 mW/mm² Luminescent spectra are corrected for variations in lamp and detector intensity with files from the manufacturer. PL Quantum yields were determined relative to rhodamine 6G (QY=0.95) or sulforhodamine 101 (QY=0.90). (25) Each photolysis and set of PL measurements was run on multiple batches of QDs (n>3), with the exception of the CdHgTe/CdS QDs and CdSe/CdS dot/rods, which were run once. Because there was significant batch-to-batch variation in PL quantum yields, and because these varied over time for a single batch, we do not average the PL values here.

### REFERENCES

(1) (a) Mitchison, T. J.; Sawin, K. E.; Theriot, J. A.; Gee, K.; Mallavarapu, A., Methods Enzymol. 1998, 291, 63-78. (b) Politz, J. C., Trends Cell Biol. 1999, 9, 284-287.
(2) Patterson, G. H.; Lippincott-Schwartz, J., Science 2002, 297, 1873-1877.
(3) (a) Wiedenmann, J.; Ivanchenko, S.; Oswald, F.; Schmitt, F.; Rocker, C.; Salih, A.; Spindler, K. D.; Nienhaus, G. U., Proc. Natl. Acad. Sci. U.S.A. 2004, 101, 15905-15910. (b) Ando, R.; Hama, H.; Yamamoto-Hino, M.; Mizuno, H.; Miyawaki, A., Proc. Natl. Acad. Sci. U.S.A. 2002, 99, 12651-12656. (c) Habuchi, S.; Ando, R.; Dedecker, P.; Verheijen, W.; Mizuno, H.; Miyawaki, A.; Hofkens, J., Proc. Natl. Acad. Sci. U.S.A. 2005, 102, 9511-9516.
(4) (a) Betzig, E.; Patterson, G. H.; Sougrat, R.; Lindwasser, 0. W.; Olenych, S.; Bonifacino, J. S.; Davidson, M. W.; Lippincott-Schwartz, J.; Hess, H. F., Science 2006, 313, 1642-1645. (b) Hess, S. T.; Girirajan, T. P. K.; Mason, M. D., Biophys. J. 2006, 91, 4258-4272. (c) Moerner, W. E., Proc. Natl. Acad. Sci. U.S.A. 2007, 104, 12596-12602.
(5) Shroff, H.; Galbraith, C. G.; Galbraith, J. A.; White, H.; Gillette, J.; Olenych, S.; Davidson, M. W.; Betzig, E., Proc. Natl. Acad. Sci. U.S.A. 2007, 104, 20308-20313.
(6) (a) Adams, S. R.; Tsien, R. Y., Ann. Rev. Physiol. 1993, 55, 755-784. (b) Mayer, G.; Heckel, A., Angew. Chem. Int. Edit. 2006, 45, 4900-4921.
(7) Mccray, J. A.; Trentham, D. R., Annu. Rev. Biophys. Bio. 1989, 18, 239-270.
(8) (a) Wuister, S. F.; Donega, C. D.; Meijerink, A., J. Phys. Chem. B 2004, 108, 17393-17397. (b) Tomasulo, M.; Yildiz, I.; Raymo, F. M., J. Phys. Chem. B 2006, 110, 3853-3855. (c) Schmelz, 0.; Mews, A.; Basche, T.; Herrmann, A.; Mullen, K., Langmuir 2001, 17, 2861-2865. (d) Yiidiz, I.; Tomasulo, M.; Raymo, F. M., Proc. Natl. Acad. Sci. U.S.A. 2006, 103, 11457-11460. (e) Huang, H.; Dorn, A.; Nair, G. P.; Bulovic, V.; Bawendi, M. G., Nano Lett. 2007, 7, 3781-3786. (f) Zhu, L. Y.; Zhu, M. Q.; Hurst, J. K.; Li, A. D. Q., J. Am. Chem. Soc. 2005, 127, 8968-8970. (g) Huang, J.; Stockwell, D.; Huang, Z.; Mohler, D. L.; Lian, T. Q., J. Am. Chem. Soc. 2008, 130, 5632-5633.
(9) Clarke, S. J.; Hollmann, C. A.; Zhang, Z. J.; Suffern, D.; Bradforth, S. E.; Dimitrijevic, N. M.; Minarik, W. G.; Nadeau, J. L., Nat. Mater. 2006, 5, 409-417.
(10) (a) Hammer, N. I.; Early, K. T.; Sill, K.; Odoi, M. Y.; Emrick, T.; Barnes, M. D., J. Phys. Chem. B 2006, 110, 14167-14171. (b) Liu, J. S.; Tanaka, T.; Sivula, K.; Alivisatos, A. P.; Frechet, J. M. J., J. Am. Chem. Soc. 2004, 126, 6550-6551. (c) Shang, Q. K.; Wang, H. D.; Yu, H.; Shan, G. Y.; Yan, R., Colloid Surface A 2007, 294, 86-91. (d) Fomenko, V.; Nesbitt, D. J., Nano Lett. 2008, 8, 287-293.
(11) Gaponik, N.; Talapin, D. V.; Rogach, A. L.; Hoppe, K.; Shevchenko, E. V.; Kornowski, A.; Eychmuller, A.; Weller, H., J. Phys. Chem. B 2002, 106, 7177-7185.
(12) Peng, H.; Zhang, L. J.; Soeller, C.; Travas-Sejdic, J., J. Luminescence 2007, 127, 721-726.
(13) Clapp, A. R.; Goldman, E. R.; Mattoussi, H., Nat. Protoc. 2006, 1, 1258-1266.
(14) Cohen, B. E.; Stoddard, B. L.; Koshland, D. E., Biochemistry 1997, 36, 9035-9044.
(15) Liu, W.; Howarth, M.; Greytak, A. B.; Zheng, Y.; Nocera, D. G.; Ting, A. Y.; Bawendi, M. G., J. Am. Chem. Soc. 2008, 130, 1274-1284.
(16) Yu, W. W.; Qu, L. H.; Guo, W. Z.; Peng, X. G., Chem. Mater. 2003, 15, 2854-2860.
(17) Jasieniak, J.; Mulvaney, P., J. Am. Chem. Soc. 2007, 129, 2841-2848.
(18) Talapin, D. V.; Rogach, A. L.; Shevchenko, E. V.; Kornowski, A.; Haase, M.; Weller, H., J. Am. Chem. Soc. 2002, 124, 5782-5790.
(19) Xie, R.; Battaglia, D.; Peng, X., J. Am. Chem. Soc. 2007, 129, 15432-15433.
(20) Tsay, J. M.; Pflughoefft, M.; Bentolila, L. A.; Weiss, S., J. Am. Chem. Soc. 2004, 126, 1926-1927.
(21) Talapin, D. V.; Koeppe, R.; Gotzinger, S.; Kornowski, A.; Lupton, J. M.; Rogach, A. L.; Benson, 0.; Feldmann, J.; Weller, H., Nano Lett. 2003, 3, 1677-1681.
(22) Shembekar, V. R.; Chen, Y. L.; Carpenter, B. K.; Hess, G. P., Biochemistry 2007, 46, 5479-5484.
(23) Wilcox, M.; Viola, R. W.; Johnson, K. W.; Billington, A. P.; Carpenter, B. K.; Mccray, J. A.; Guzikowski, A. P.; Hess, G. P., J. Org. Chem. 1990, 55, 1585-1589.
(24) (a) Guo, J.; Yang, W. L.; Wang, C. C., J. Phys. Chem. B 2005, 109, 17467-17473. (b) Shavel, A.; Gaponik, N.; Eychmuller, A., J. Phys. Chem. B 2006, 110, 19280-19284.
(25) Kubin, R. F.; Fletcher, A. N., J. Luminescence 1982, 27, 455-462.

The preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

That which is claimed is:

1. A caged semiconductor nanocrystal, comprising:
a semiconductor nanocrystal; and
chemical moiety bound to or associated with the semiconductor nanocrystal, wherein the chemical moiety renders the semiconductor nanocrystal non-luminescent, and further wherein the chemical moiety is cleaved from the semiconductor nanocrystal by the application of violet or ultraviolet light.

2. The caged semiconductor nanocrystal as claimed in claim 1, wherein the chemical moiety is an aromatic group.

3. The semiconductor nanocrystal as claimed in claim 1, wherein, the chemical moiety is an ortho-nitrobenzyl (ONB) group.

4. The caged semiconductor nanocrystal of claim 1, wherein the semiconductor nanocrystal is comprised of a core and a shell.

5. The caged semiconductor nanocrystal of claim 4, wherein the core is comprised of CdTe and the shell is comprised of CdS.

6. The caged semiconductor nanocrystal of claim 3, wherein the ONB is covalently bound to the semiconductor nanocrystal.

7. The caged semiconductor nanocrystal of claim 1, wherein the semiconductor nanocrystal is comprised of Group II-VI semiconductors.

8. The caged semiconductor nanocrystal of claim 1, wherein the semiconductor nanocrystal is comprised of a semiconductor selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

9. The caged semiconductor nanocrystal of claim 1, wherein the semiconductor nanocrystal is comprised of Group III-V semiconductors.

10. The caged semiconductor nanocrystal of claim 1, wherein the semiconductor nanocrystal is comprised of a semiconductor selected from the group consisting of GaAs, InGaAs, InP, and InAs.

11. A caged semiconductor nanocrystal, comprising:
a semiconductor nanocrystal; and
an ortho-nitrobenzyl (ONB) covalently bound to the semiconductor nanocrystal, wherein the ONB group renders the semiconductor nanocrystal non-luminescent and further wherein exposing the caged semiconductor nanocrystal to light in a wavelength in a range of 300 nm to 420 nm cleaves the ONB from the semiconductor nanocrystal and renders the semiconductor nanocrystal luminescent.

12. A caged luminescent semiconductor nanocrystal compound capable of linking to an affinity molecule and capable of emitting electromagnetic radiation in a narrow wavelength band when excited, comprising:
a) a semiconductor nanocrystal capable of emitting light in a narrow wavelength band when excited;
b) a linking agent linked to said semiconductor nanocrystal and capable of linking to said affinity molecule; and
c) a chemical moiety associated with the semiconductor nanocrystal which moiety quenches luminescence from the semiconductor nanocrystal and is separable from the semiconductor nanocrystal by the application of light.

13. The caged luminescent semiconductor nanocrystal compound of claim 12, wherein said semiconductor nanocrystal is capable of absorbing energy over a wide bandwidth.

14. The caged luminescent semiconductor nanocrystal compound of claim 12, wherein said linking agent comprises a first portion linked to said semiconductor nanocrystal and a second portion capable of linking to said affinity molecule.
